(19) United States
(12) Patent Application Publication
(10) Pub. No.: US 2006/0202222 A1
(43) Pub. Date: Sep. 14, 2006

(54) Package structure of organic electroluminescent devices

(76) Inventors: Wen-Jeng Lan, Chu-Nan (TW); Chien-Yuan Feng, Chu-Nan (TW); Yuan-Chang Tseng, Chu-Nan (TW); Ting-Chou Chen, Chu-Nan (TW); Sheng-Hsu Shih, Chu-Nan (TW); Chien-Chih Chiang, Chu-Nan (TW); Chih-Ping Lin, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/372,019

(22) Filed: Mar. 10, 2006

(30) Foreign Application Priority Data
Mar. 14, 2005 (CN) 200510053928.7

(51) Int. Cl. H01L 33/00

(52) U.S. Cl. 257/98

(57) ABSTRACT

A package structure of organic electroluminescent device comprises at least one isolating wall and at least one squeeze-out channel provided under a package lid. The adhesive coating place and squeeze-out area as laminating are able to be defined in package process due to the isolating wall and squeeze-out channel provided, therefore, which is not only to prevent the adhesive squeezed out from package process to protect the emitting element within the package lid, but also prevent the adhesive squeezing out of the package lid to the saw street to affect the further cutting process.

### FIELD OF THE INVENTION

The present invention relates to a package structure, and more particularly to a package structure of organic electroluminescent device, not only preventing the adhesive squeezed out from package process to protect the emitting element within the package lid, but also preventing the adhesive squeezing out of the package lid to the saw street to affect the further cutting process.

### BACKGROUND OF THE INVENTION

The comparison between organic electroluminescent device and other light emitting structures, the organic electroluminescent device provides more advantages of self-illumination, brighter, wider viewing angle, smaller power consumption, faster response time, thinner panel, and simple manufacturing, therefore, there is paid more attention by every researcher and manufacture.

As shown on FIG. 1A, FIG. 1B, and FIG. 1C, the prior art organic electroluminescent device 10 in the package process, provides at least one organic light emitting element 13 on the top of a substrate 11. A package lid 17 covers the organic light emitting element 13 to form a protection package structure. An adherend 15 is coated on an adhesive coating place 172 for adhering the substrate 11 and the package lid 17 to prevent the outside air or water from getting into the space 19 formed between the package lid 17 and the substrate 11.

Not only the package lid 17 can prevent the outside air and water from getting into the space 19, but also the adherend 15 placed between the substrate 11 and the package lid 17 with an additional force F to adhere the adherend 15, the substrate 11 and the package lid 17 tight for preventing any gap between the substrate 11 and package lid 17 or falling off each other. However, according to the additional force F pressing as the adherend 15 laminating, the adherend 15 will be deformed to form an internal adhesive squeezed out 151 and an external adhesive squeezed out 153.

Once the internal adhesive squeezed out 151 and organic light emitting element 13 are in touch with each other, the organic light emitting element 13 will be broken, which may affect the yield rate of the organic electroluminescent device. And, the external adhesive squeezed out 153 may overflow to the saw street 115 to affect the further cutting process.

Besides, in the package process, the adherend 15 is placed and provided on the height unequivocally, therefore, which may increase the difficulty of manufacturing and disadvantage for the mass production.

### SUMMARY OF THE INVENTION

Accordingly, how to design a novel package structure of organic electroluminescent device with respect to the previous mentioned shortcomings of the prior art, not only preventing the adhesive squeezed out from package process to protect the emitting element within the package lid, but also preventing the adhesive squeezing out of the package lid to the saw street to affect the further cutting process, which be able to increase the yield rate of the organic electroluminescent device and manufacturing efficiency is the key point of the present invention. Therefore,

It is a primary object of the present invention to provide a package structure of organic electroluminescent device, comprising at least one isolating wall under the package lid for preventing the adhesive squeezed out, and increasing the yield rate of the organic electroluminescent device.

It is a secondary object of the present invention to provide a package structure of organic electroluminescent device, comprising at least one squeeze-out channel under the package lid for collecting the surplus adherend as laminating, and reducing the adhesive squeezed out.

It is another object of the present invention to provide a package structure of organic electroluminescent device, which be able to define the coating place and provided height of the adherend according to the isolating wall and squeeze-out channel for reducing the difficulty of manufacturing and benefiting for mass production.

To achieve the previous mentioned objects, the present invention provides a package structure of organic electroluminescent device comprising: a substrate, comprising at least one organic light emitting element provided on the surface thereof; a package lid provided on the top of the substrate for covering the organic light emitting element; and a plurality of isolating walls provided on a adhesive coating place of the package lid, a seal area formed between each isolating wall, comprising an adherend within the internal thereof, adhering the package lid on said substrate by the adherend.

To achieve the previous mentioned objects, the present invention further provides a package structure of organic electroluminescent device, comprising: a substrate, comprising at least one organic light emitting element provided on the surface thereof; a package lid provided on the top of the substrate for covering the organic light emitting element; at least one isolating wall and at least one squeeze-out channel provided around a adhesive coating place of the package lid, a seal area formed between each isolating wall; and an adherend provided within the seal area, adhering the package lid on the substrate.

### BRIEF DESCRIPTION OF THE DRAWINGS

It will be understood that the figures are not to scale since the individual layers are too thin and the thickness differences of various layers too great to permit depiction to scale.

FIG. 1A is a vertical view of a prior art package structure;

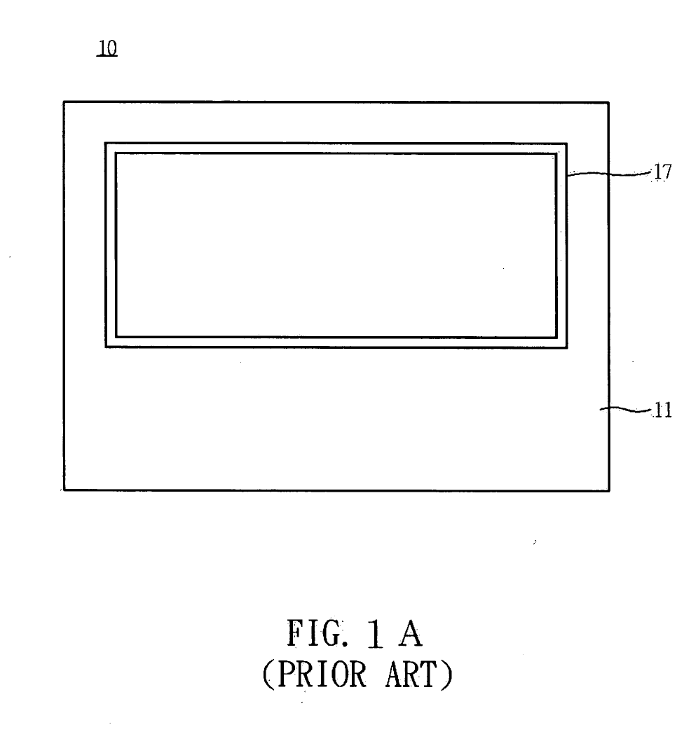

FIG. 1B is a cross-sectional view of the prior art package structure;

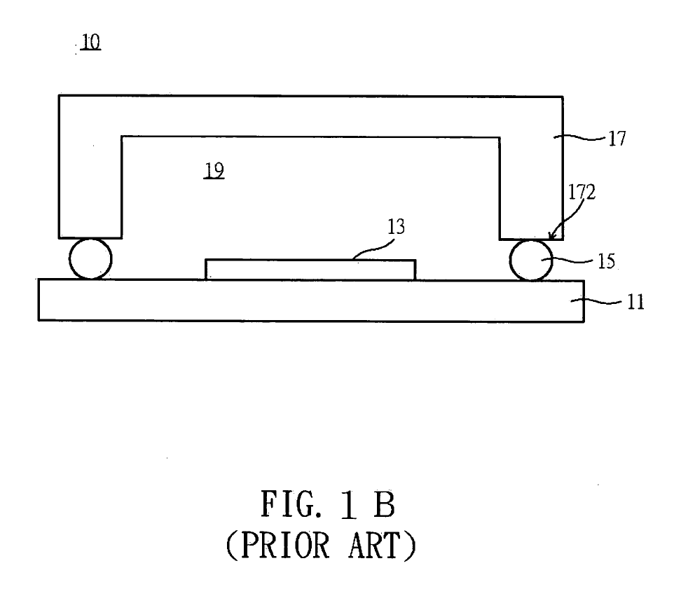

FIG. 1C is a cross-sectional view of the prior art package structure;

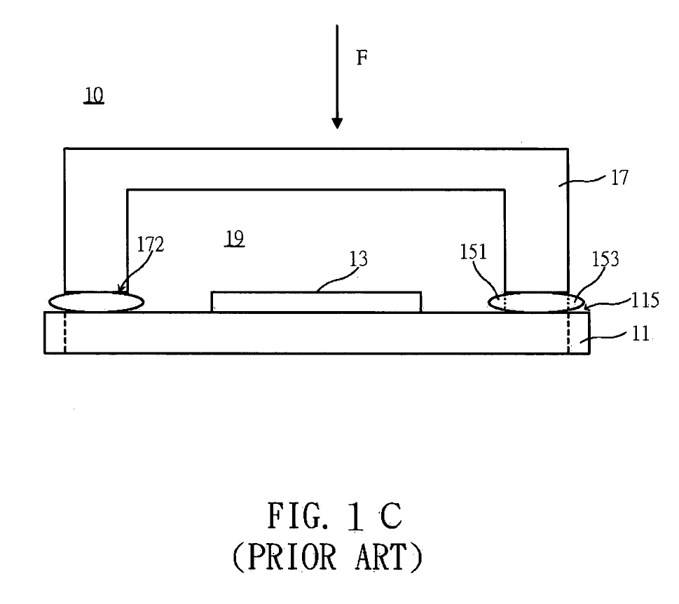

FIG. 2A is a vertical view of a preferred embodiment of the present invention;

FIG. 2B is a cross-sectional view of the previous embodiment of the present invention;

FIG. 2C is a partial enlargement view of the previous embodiment of the present invention;

FIG. 3A is a vertical view of another embodiment of the present invention;

FIG. 3B is a cross-sectional view of the previous embodiment of the present invention;

FIG. 4A is a vertical view of another embodiment of the present invention;

FIG. 4B is a cross-sectional view of the previous embodiment of the present invention;

FIG. 5A is a vertical view of another embodiment of the present invention; and

FIG. 5B is a cross-sectional view of the previous embodiment of the present invention.

### DETAILED DESCRIPTION OF THE INVENTION

The structural features and the effects to be achieved may further be understood and appreciated by reference to the presently preferred embodiments together with the detailed description.

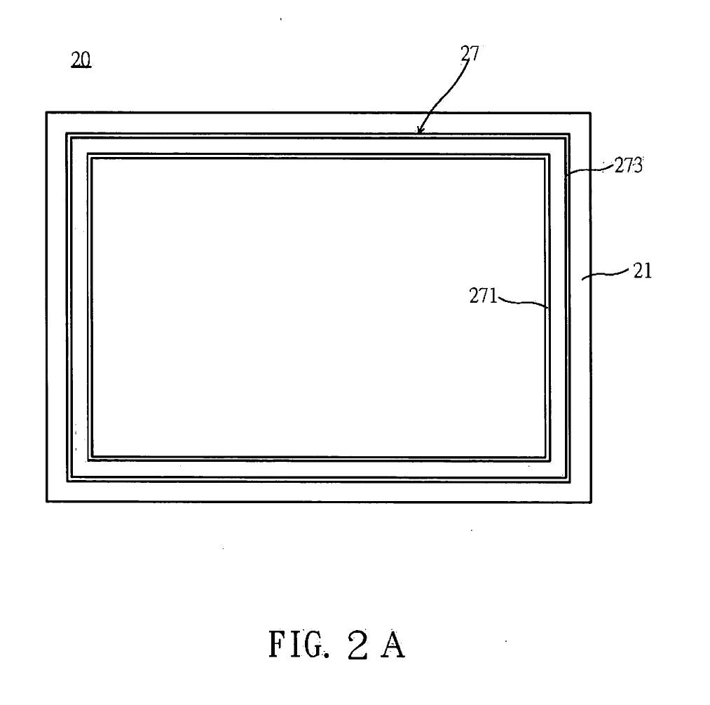

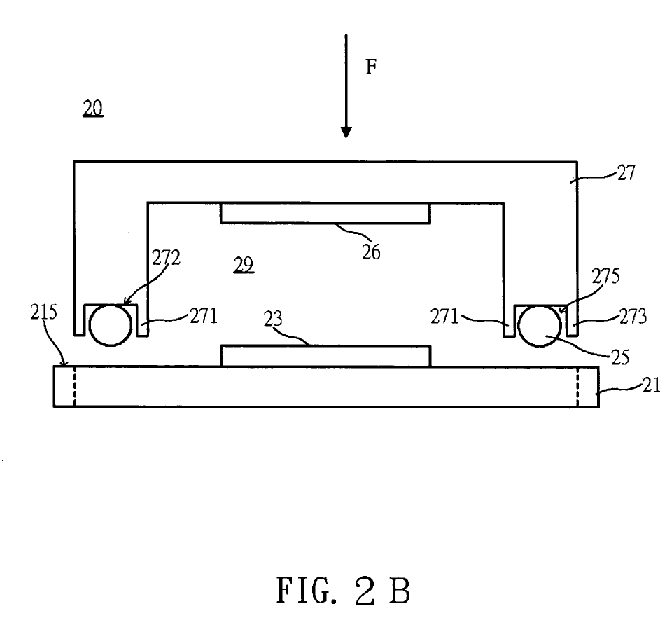

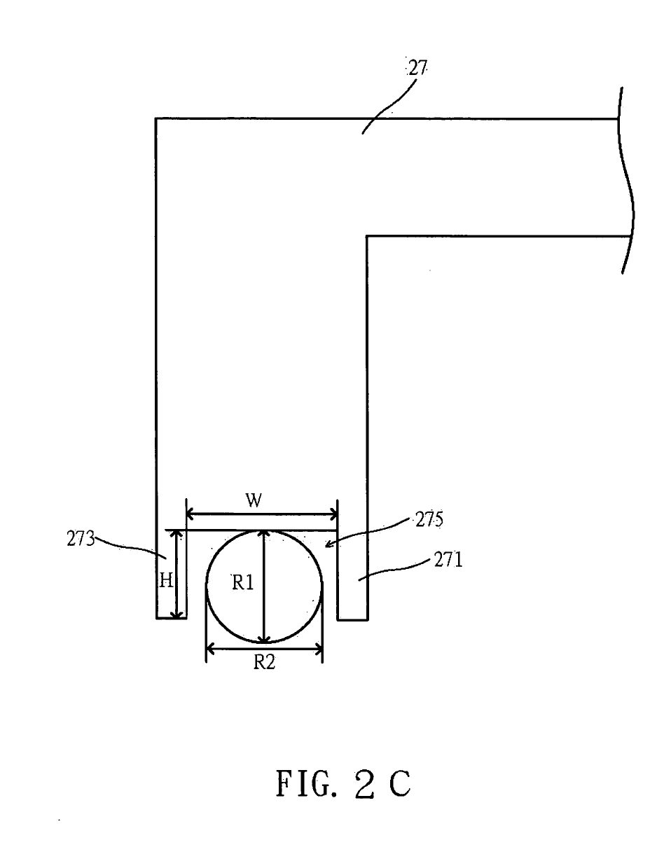

Referring to FIG. 2A, FIG. 2B, and FIG. 2C, are respectively a vertical view, a cross-sectional view, and a partial enlargement view of a preferred embodiment of the present invention. The package structure of the organic electroluminescent device 20 comprises a substrate 21, the surface thereof comprising at least one organic light emitting element 23, which comprising a package lid 27 provided on the top thereof. The package lid 27 is used for covering the organic light emitting element 23 to form a protection package structure. The adhesive coating place 272 of the package lid 27 comprises at least one isolating wall, such as the internal isolating wall 271 and external isolating wall 273. And, a seal area 275 is formed between the internal isolating wall 271, external isolating wall 273, and package lid 27. The seal area 275 can be defined as the place for placing an adherend 25. The substrate 21 and the package lid 27 can be adhered tight by the adherend 25 to prevent the outside air and water from getting into the space 29 formed between the package lid 27 and the substrate 21. Finally, the organic light emitting element 23 within the space 29 is protected. Further, the life time of organic electroluminescent device 20 will be extended.

As placing the adherend 25 on the seal area 275, the height R1 of the adherend 25 is larger than the deepness H of the seal area 275, which may sure the tight touch of the package lid 27 and the substrate 21 as laminating. And, the wideness R2 of the adherend 25 is smaller than the wideness W of the seal area 275, which may keep a space as extended space for the adherend 27 deforming by an additional force (F) to reduce the possibility of adherend 25 squeezing out.

In accordance with placing of the internal isolating wall 271 and external isolating wall 273, the coating place 275 of the adherend 25 and provided height R1 thereof can be defined, which simplify the difficulty of manufacturing and benefit the mass production. The internal isolating wall 271, external isolating wall 273, and the seal area 275 are provided for easily controlling and collecting the adherend 25 in the adhesive flowing area as laminating. Therefore, not only the organic light emitting element 23 within the space 29 can be protected, but also the adherend 25 will not be squeezed out of package lid 27 to the saw street 215, which benefits the proceeding of the further process.

The adherend 25 is selected from a hot-setting adhesive or an ultraviolet ray setting adhesive, such as the polymer of epoxy resin or acrylic acid resin and so on.

The space 29 formed by the package lid 27 and the substrate 21 further comprises at least one dried layer 26 therein, for absorbing the internal water to reduce the possibility of water contact from the organic light emitting element 23, which be able to increase the life time of the organic electroluminescent device 20.

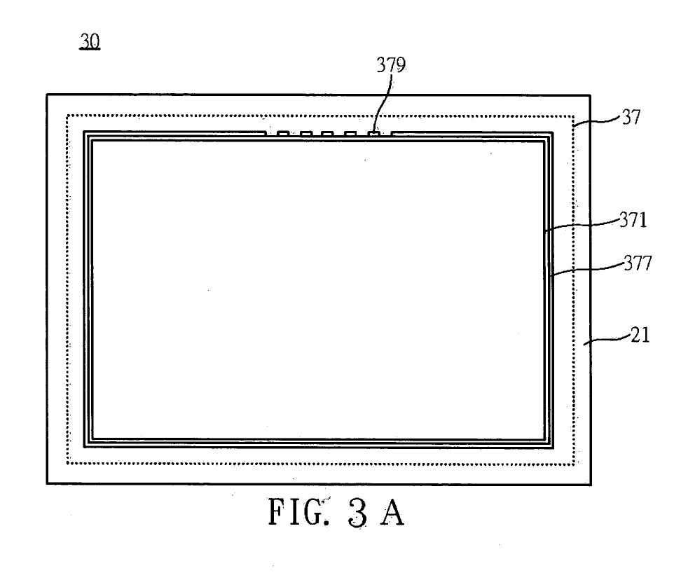

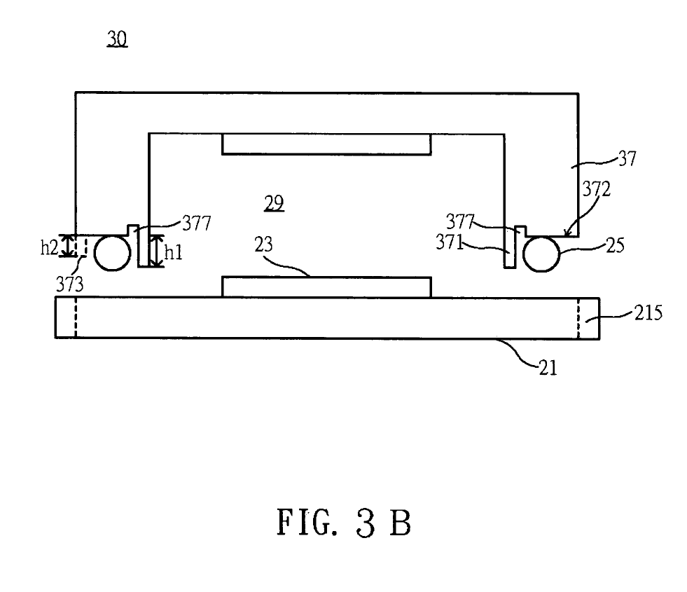

Referring to FIG. 3A, and FIG. 3B, are respectively a vertical view and a cross-sectional view of another embodiment of the present invention. The organic electroluminescent device 30 comprises an organic light emitting element 23 provided on the surface of the substrate 21, a package lid 37 covering on the top of the substrate 21. The adhesive coating place 372 of the package lid 37 comprises an internal isolating wall 371 and a squeeze-out channel 377.

The internal isolating walls 371 are provided for preventing the partial adherend 25 squeezed out from the organic electroluminescent device in the package process. The squeeze-out channel is provided as another space for the adherend 25, which can increase the adhering for adherend 25 and package lid 37, and reduce the possibility of adherend 25 squeezed out.

The squeeze-out channels 377 are provided around under the package lid 37 as in the intermittent or the continuous way depending on the selection. And, as the squeeze-out channels 377 intermittently provided, the squeeze-out channel can be selected to consist of a plurality of intermittent squeeze-out holes 379.

In the embodiment of the present invention, the external isolating wall 373 can be selected to be absence. Therefore, the adherend 25 is possibly squeezed out to the saw street 215, but the coating quantity of the adherend 25 can be controlled as in package process. Additionally, according to the internal isolating wall 371 and the squeeze-out channel 377 provided, the partial squeezed out adherend 25 will not affect the cutting process for the organic electroluminescent device 30.

In accordance with another embodiment of the present invention, the height of the external isolating wall 373 and the internal isolating wall 371 can be selectively designed to be different for ensuring that the partial adherend 25 will not be squeezed stay in the space 29. Therefore, the height h2 of the external isolating wall 373 is lower than the height h1 of the internal isolating wall 371. And, when the coating quantity of the adherend 25 is over, the internal isolating wall 371 and the external isolating wall 373 can limit the squeezed flowing direction to the seal area 375 or squeeze-out channel 377 firstly. Once the coating quantity is still too much, the partial adherend 25 can be selected to squeeze out from the lower height of the external isolating wall 373 to protect that the organic light emitting element 23 won't be affected.

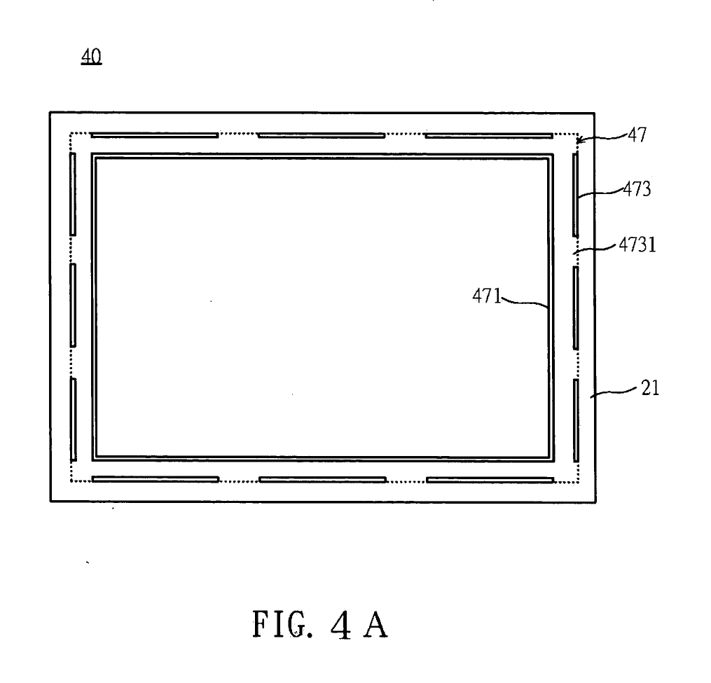

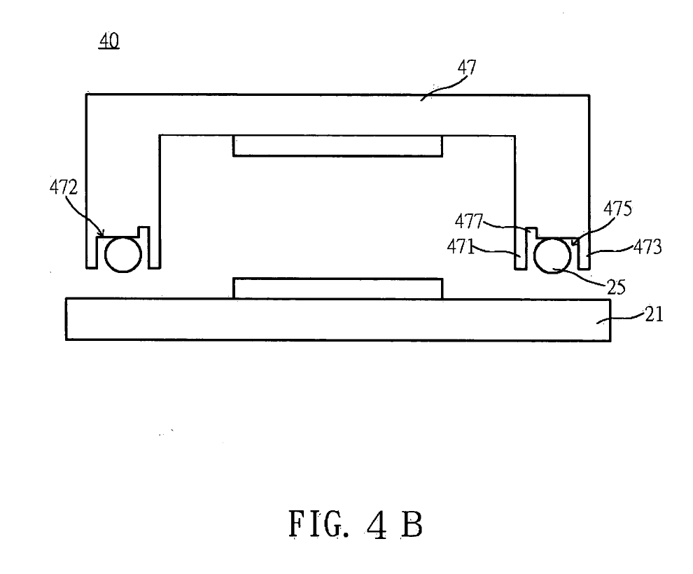

Referring to FIG. 4A and FIG. 4B, are respectively a vertical view and a cross-sectional view of another embodiment of the present invention. The organic electroluminescent device 40 comprises an internal isolating wall 471, an external isolating wall 473, and an internal squeeze-out channel 477 provided around the adhesive coating place 472 of the package lid 47.

The internal isolating wall 471, the external isolating wall 473, and the internal squeeze-out channel 477 are provided as in the intermittent or the continuous way depending on selection. Once the internal isolating wall 471 and the external isolating wall 473 are continuously provided, the adherend 25 can be totally limited within the seal area 475 formed between the internal isolating wall 471 and the external isolating wall 473, which isolates the possibility of the adherend 25 squeezed out, and increases the yield rate of the product.

And, once the internal isolating wall 471 and the external isolating wall 473 are intermittently provided, the adherend 25 may be squeezed out from the joint 4731, but the proper squeezed out adherend can increase the contact area of the adherend 25, the substrate 21, and the package lid 47 to improve the adhering of the substrate 21 and the package lid 47. Therefore, controlling the quantity of adherend 25, can improve the adhering of the substrate 21 and the package lid 47 without affecting the proceeding of further process.

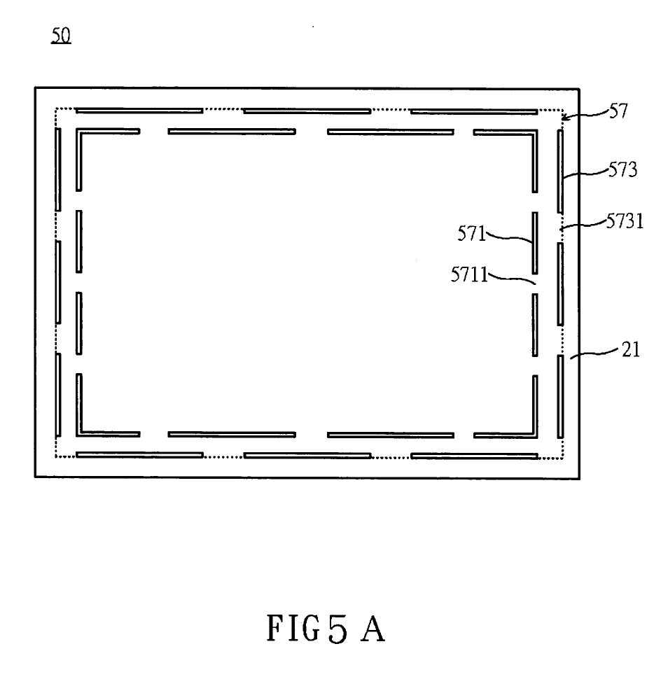

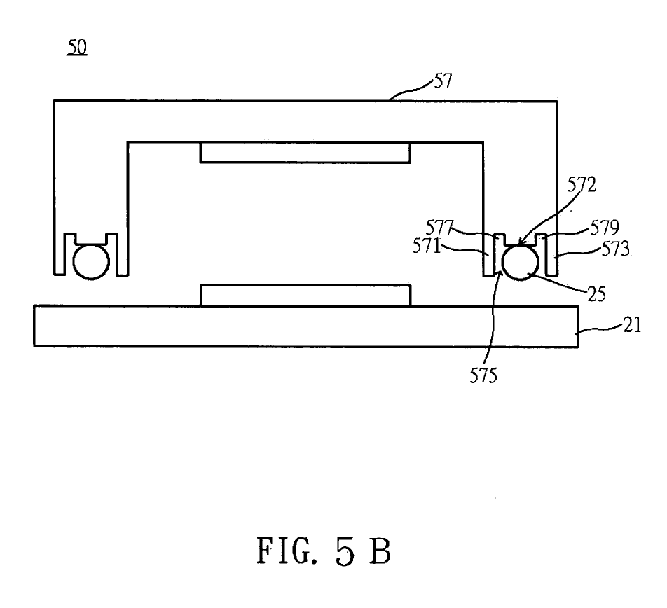

Referring to FIG. 5A and FIG. 5B, are respectively a vertical view and a cross-sectional view of another embodiment of the present invention. The organic electroluminescent device 50 comprises an internal isolating wall 571, an external isolating wall 573, an internal squeeze-out channel 577, and an external squeeze-out channel 579 provided around the adhesive coating place 572 of the package lid 57. The internal isolating wall 571 and the external isolating wall 573 are intermittently provided as in the interlaced way.

When the internal isolating wall 571 and the external isolating wall 573 are intermittently provided as in the interlaced way, the adherend 25 may be squeezed in the internal direction from the joint 5711 of the internal isolating wall 571 or squeezed out from the joint 5731 of the external isolating wall 573. However, the surplus adherend 25 can be directed into the internal squeeze-out channel 577 and the external squeeze-out channel 579 according to control the quantity of adherend 25 and corresponding to the internal squeeze-out channel 577 and the external squeeze-out channel 579 provided. Further, the quantity of the squeezed out adherend can be controlled, such as once the volume of filled adherend 25 is bigger than the seal area 575, the partial adherend 25 will be squeezed out, which will increase the contact area of the adherend 25, substrate 21, and the package lid 57, and improve the adhering of the substrate 21 and the package lid 47 without affecting the proceeding of further process.

In summary, it is appreciated that the present invention is not only to prevent the adhesive squeezed out from package process to protect the emitting element within the package lid, but also prevent the adhesive squeezing out to the saw street to effect the further cutting process.

The foregoing description is merely one embodiment of present invention and not considered as restrictive. All equivalent variations and modifications in process, method, feature, and spirit in accordance with the appended claims may be made without in any way from the scope of the invention.

I claim:

1. A package structure of organic electroluminescent device, comprising:
a substrate, comprising at least one organic light emitting element provided on the surface thereof;
a package lid provided on the top of said substrate for covering said organic light emitting element; and
a plurality of isolating walls provided on an adhesive coating place of said package lid, a seal area formed between each said isolating wall, comprising an adherend within the internal thereof, adhering said package lid on said substrate by said adherend.

2. The package structure of claim 1, wherein said adhesive coating place of said package lid further comprises at least one squeeze-out channel.

3. The package structure of claim 1, wherein said isolating wall further comprises an internal isolating wall and an external isolating wall.

4. The package structure of claim 3, wherein the height of said external isolating wall is smaller than said internal isolating wall.

5. The package structure of claim 1, wherein the height of said adherend is larger than the deepness of said seal area.

6. The package structure of claim 2, wherein said squeeze-out channel comprises an external squeeze-out channel and an internal squeeze-out channel.

7. The package structure of claim 1, wherein said isolating walls are intermittently provided around said adhesive coating place of said package lid, a joint provided between each said isolating wall.

8. The package structure of claim 2, wherein said squeeze-out channel consists of a plurality of squeeze-out holes.

9. The package structure of claim 1, wherein said package lid further comprises a dried layer.

10. A package structure of organic electroluminescent device, comprising:
a substrate, comprising at least one organic light emitting element provided on the surface thereof;
a package lid provided on the top of said substrate for covering said organic light emitting element;
at least one isolating wall and at least one squeeze-out channel provided around a adhesive coating place of said package lid, a seal area formed between each said isolating wall; and
an adherend provided within said seal area, adhering said package lid on said substrate.

11. The package structure of claim 10, wherein said isolating wall further comprises an internal isolating wall and an external isolating wall.

12. The package structure of claim 11, wherein the height of said external isolating wall is smaller than said internal isolating wall.

13. The package structure of claim 10, wherein the height of said adherend is larger than the deepness of said seal area.

14. The package structure of claim 10, wherein said squeeze-out channel comprises an external squeeze-out channel and an internal squeeze-out channel.

15. The package structure of claim 10, wherein said isolating walls are intermittently provided around said adhesive coating place of said package lid, a joint provided between each said isolating wall.

16. The package structure of claim 10, wherein said squeeze-out channel consists of a plurality of squeeze-out holes.

17. The package structure of claim 10, wherein said package lid further comprises a dried layer.
